(19) United States
(12) Patent Application Publication
(10) Pub. No.: US 2024/0234148 A1
(43) Pub. Date: Jul. 11, 2024

(54) METHOD FOR FABRICATING ELECTRODE AND SEMICONDUCTOR DEVICE INCLUDING THE SAME

(71) Applicant: SK hynix Inc., Icheon-si (KR)

(72) Inventors: Cha Deok DONG, Icheon-si (KR); Jeong Myeong KIM, Icheon-si (KR); Keo Rock CHOI, Icheon-si (KR)

(21) Appl. No.: 18/344,583

(22) Filed: Jun. 29, 2023

(30) Foreign Application Priority Data
Jan. 11, 2023 (KR) 10-2023-0004027

(51) Int. Cl. H01L 21/223; H01L 21/02; H01L 21/265; H01L 21/311

(52) U.S. Cl. CPC H01L 21/2236; H01L 21/02164; H01L 21/0217; H01L 21/26506; H01L 21/31122

(57) ABSTRACT

A method for fabricating an electrode may include: forming a carbon layer; performing an ion beam etch process to planarize and harden a surface of the carbon layer on the carbon layer; and performing an impurity doping process to dope an impurity into the carbon layer.

### PRIORITY CLAIM AND CROSS-REFERENCE TO RELATED APPLICATION

This patent document claims the priority and benefits of Korean Patent Application No. 10-2023-0004027 filed on Jan. 11, 2023, which is incorporated herein by reference in its entirety.

### TECHNICAL FIELD

This patent document relates to integrated circuit designs and their applications in semiconductor devices or systems including memory circuits or devices.

### BACKGROUND

The recent trend toward miniaturization, low power consumption, high performance, and multi-functionality in the electrical and electronics industry has compelled the semiconductor manufacturers to focus on high-performance, high capacity semiconductor devices. Examples of such high-performance, high capacity semiconductor devices include, but are not limited, memory devices that can store data by switching between different resistance states according to an applied voltage or current. The semiconductor devices may include an RRAM (resistive random access memory), a PRAM (phase change random access memory), an FRAM (ferroelectric random access memory), an MRAM (magnetic random access memory), and an electronic fuse (E-fuse).

### SUMMARY

The disclosed technology in this patent document relates to designs and fabrication of electrodes in integrated circuits or devices and their applications in semiconductor devices or systems including memory circuits and devices. Various implementations of a semiconductor device can improve the performance of a semiconductor device and reduce manufacturing defects.

In one aspect, a method for fabricating an electrode may include: forming a carbon layer; performing an ion beam etch process on the carbon layer to planarize and harden a surface of the carbon layer; and performing an impurity doping process to dope an impurity into the carbon layer. In some implementations, the carbon layer is transformed into an electrode after the ion beam etch process and the impurity doping process.

In another aspect, a method for fabricating a semiconductor device for implementing the disclosed technology may include: forming a first electrode layer over a substrate; forming a nitride layer and an oxide layer over the first electrode layer; doping the nitride layer and the oxide layer with a dopant by an ion implantation process to form a selector layer; and forming a second electrode layer over the selector layer, wherein at least one of the forming of the first electrode layer or the forming of the second electrode layer comprises: forming a carbon layer; performing an ion beam etch process on the carbon layer to planarize and harden a surface of the carbon layer; and performing an impurity doping process to dope an impurity into the carbon layer.

The above and other aspects of the disclosed technology are disclosed in the drawings, the detailed description and the claims.

### BRIEF DESCRIPTION OF THE DRAWINGS

FIGS. 1A to 1C illustrate an example of a method for forming an electrode based on some implementations of the disclosed technology.

FIGS. 2A and 2B illustrate an example of a semiconductor device based on some implementations of the disclosed technology.

FIGS. 3A to 3J illustrate an example of a method for a semiconductor device based on some implementations of the disclosed technology.

FIGS. 4 to 8 illustrate another example of a semiconductor device based on some implementations of the disclosed technology.

### DETAILED DESCRIPTION

Hereinafter, various embodiments of the disclosure will be described in detail with reference to the accompanying drawings.

The drawings are not necessarily drawn to scale. In some instances, proportions of at least some structures in the drawings may have been exaggerated in order to clearly illustrate certain features of the described embodiments. In presenting a specific example in a drawing or description having two or more layers in a multi-layer structure, the relative positioning relationship of such layers or the sequence of arranging the layers as shown reflects a particular implementation for the described or illustrated example and a different relative positioning relationship or sequence of arranging the layers may be possible. In addition, a described or illustrated example of a multi-layer structure might not reflect all layers present in that particular multilayer structure (e.g., one or more additional layers may be present between two illustrated layers). As a specific example, when a first layer in a described or illustrated multi-layer structure is referred to as being “on” or “over” a second layer or “on” or “over” a substrate, the first layer may be directly formed on the second layer or the substrate but may also represent a structure where one or more other intermediate layers may exist between the first layer and the second layer or the substrate.

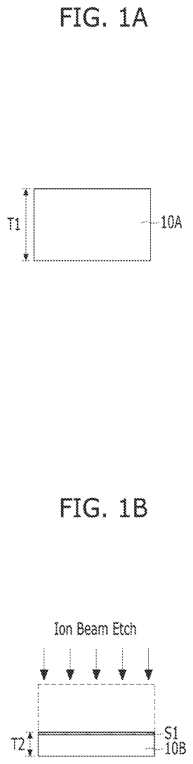

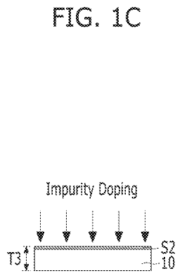

FIGS. 1A to 1C illustrate an example of a method for forming an electrode based on some implementations of the disclosed technology.

In the implementation shown in FIGS. 1A to 1C, a method for forming the electrode itself is described and the description of structures other than the electrode is omitted.

Referring to FIG. 1A, a carbon layer 10A may be formed.

With high resistance and high work function characteristics, there are advantages of using carbons as an electrode. For example, in a memory cell in which a selector layer and a memory layer are stacked at a lower portion and an upper portion of the same element, when a carbon electrode is applied as an electrode adjacent to the selector layer, it is possible to form a stable and uniform selector layer compared to other electrodes, e.g., a metal electrode, a nitride-cased electrode, or a silicide-based electrode.

The carbon layer 10A may be formed to have a thickness of T1.

The carbon layer 10A may be formed by a physical vapor deposition method, for example, a sputtering method.

Referring to FIG. 1B, an ion beam etch process may be performed on the carbon layer 10A. Through the ion beam etch process, the thickness of the carbon layer 10A may be reduced and a surface of the carbon layer 10A may be planarized and hardened. The carbon layer 10A after the ion beam etch process may be referred to as an initial electrode 10B.

Since the carbon layer 10A is deposited by a sputtering method or others, the surface roughness is poor and the layer is unstable. In this case, during forming a selector layer including an insulating layer with a dopant, carbon may be easily lost, making it difficult to preserve a shape of an electrode. Further, the film quality of the selector layer may be deteriorated and an operating voltage of a memory cell may not be uniform.

In the implementations, by performing an ion beam etch process on the carbon layer 10A, remaining part 10B of the carbon layer 10Acan be of a thickness that is sufficiently thin to facilitate electrode isolation and maintain a stability of the surface roughness. This remaining part 10B of the carbon layer 10A can be transformed into an electrode by subsequent processing steps as explained later and is referred to as the “initial electrode 10B” below. Thus, the surface of the initial electrode 10B may be planarized to exhibit the sufficiently reduced surface roughness. Since the thickness of the carbon layer 10A is proportional to the surface roughness, the surface roughness of the carbon layer 10A may increases as the thickness of the carbon layer 10A increases, and the surface roughness of the carbon layer 10A may decreases as the thickness of the carbon layer 10B decreases. As a result, the surface roughness of the initial electrode 10B can be reduced compared to the carbon layer 10A before the ion beam etch process.

In some implementations, a surface portion of the initial electrode 10B is more densified than an inner portion of the initial electrode 10B. Therefore, the initial electrode 10B can have etch resistance about 3 times or more than that of the carbon layer 10A. In the initial electrode 10B, a surface portion that is planarized and has an increased hardness may be referred to as S1.

A lower limit of a thickness T2 of the initial electrode 10B may be set in consideration of stabilization of the surface roughness. In some implementations, the lower limit of the thickness T2 may be about 2 nm. An upper limit of the thickness T2 of the initial electrode 10B may vary depending on the thickness T1 of the carbon layer 10A. As the thickness T1 of the carbon layer 10A increases, the thickness T2 of the initial electrode 10B may also increase.

In some implementations, the initial electrode 10B may operate as an electrode. In some implementations, an additional process may be performed for further increasing the surface hardness of the initial electrode 10B. An example of the additional process to further increase the surface hardness of the initial electrode will be described with reference to FIG. 1C.

Referring to FIG. 1C, the initial electrode 10B may be doped with an impurity. The initial electrode 10B doped with the impurity may be referred to as an electrode 10.

Density of the electrode 10 can be increased by impurity doping, and thus resistance can be increased. Therefore, a medium of the electrode 10 can be strengthened. As a result, the surface hardness of the electrode 10 can be further increased by the impurity doping process.

In the electrode 10, a surface portion having an increased hardness may be referred to as S2.

The impurity may include nitrogen (N), or boron (B), or a combination thereof. Thus, the impurity may include at least one of nitrogen or boron.

The impurity doping process may be performed by a low energy ion implantation process or a plasma doping (PLAD) process. By doping the impurity through the low energy ion implantation process or the PLAD process, density and thus resistance of the electrode 10 can be increased to strengthen the medium of the electrode 10. Further, it is possible to increase the surface hardness and prevent deterioration of the surface roughness.

In some implementations, the low energy ion implantation process may be performed under conditions including an energy of 1-5 KeV and a dose of 1.0×10¹³−1.0×10¹⁶ cm⁻².

In some implementations, the PLAD process may be performed under conditions including an energy of 1-5 KV and a dose of 1.0×10¹³−1.0×10¹⁶ cm⁻².

The impurity doping process can provide an additional surface strengthening effect for the initial electrode 10B having a planarized surface and improved hardness. As a result, the electrode 10 can have further improved surface hardness.

The electrode 10 may be formed to have a thickness T3. Since an upper portion of the initial electrode 10B can be partially lost during the ion implantation process, the thickness T3 of the electrode 10 may be smaller than the thickness T2 of the initial electrode 10B.

The initial electrode 10B or the electrode 10 formed by the above-described method can have a sufficiently thin thickness to facilitate electrode separation while maintaining a stability of the surface roughness. Moreover, the surface of the initial electrode 10B or the electrode 10 can be densified and hardened to increase the surface hardness. Therefore, when the selector layer including an insulating layer with a dopant is formed over the initial electrode 10B or the electrode 10, it is possible to minimize the loss of carbon due to the ion implantation process.

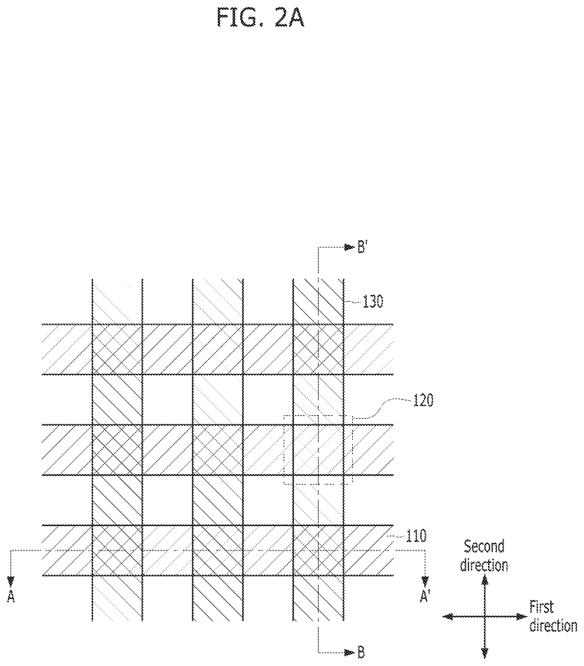

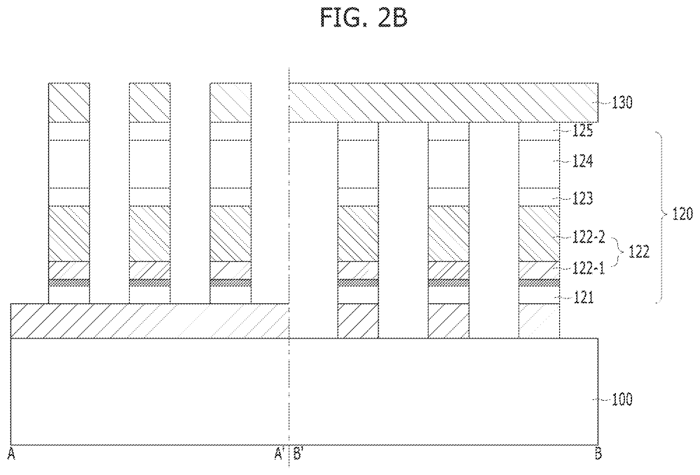

The initial electrode 10B or the electrode 10 in accordance with the implementation may be applied as an electrode of a memory cell in which a selector layer and a memory layer are stacked in a lower portion and an upper portion of the same element. This will be described with reference to FIGS. 2A and 2B.

FIGS. 2A and 2B illustrate a semiconductor device based on some implementations of the disclosed technology. FIG. 2A is a plan view, and FIG. 2B is a cross-sectional view taken along line A-A′ and line B-B′ of FIG. 2A.

Referring to FIGS. 2A and 2B, the semiconductor device may include a cross-point structure including a substrate 100, first conductive lines 110 formed over the substrate 100 and extending in a first direction, second conductive lines 130 formed over the first conductive lines 110 to be spaced apart from the first conductive lines 110 and extending in a second direction crossing the first direction, and memory cells 120 disposed at intersections of the first conductive lines 110 and the second conductive lines 130 between the first conductive lines 110 and the second conductive lines 130. In this patent document, the conductive lines can refer to any conductive structures that electrically connect two or more circuit elements in the semiconductor memory. In some implementations, the conductive lines include word lines that are used to control access to memory cells in the memory device and bit lines that are used to read out information stored in the memory cells. In some implementations, the conductive lines include interconnects that carry signals between different circuit elements in the semiconductor memory.

The substrate 100 may include a semiconductor material such as silicon. A required lower structure (not shown) may be formed in the substrate 100. For example, the substrate 100 may include a driving circuit (not shown) electrically connected to the first conductive lines 110 and/or the second conductive lines 130 to control operations of the memory cells 120. In this patent document, the conductive lines can indicate conductive structures that electrically connect two or more circuit elements in the semiconductor device. In some implementations, the conductive lines include word lines that are used to control access to memory cells in the memory device and bit lines that are used to read out information stored in the memory cells. In some implementations, the conductive lines include interconnects that carry signals between different circuit elements in the semiconductor device.

The first conductive lines 110 and the second conductive lines 130 may be connected to a lower end and an upper end of the memory cell 120, respectively, and may provide a voltage or a current to the memory cell 120 to drive the memory cell 120. When the first conductive lines 110 function as a word line, the second conductive lines 130 may function as a bit line. Conversely, when the first conductive lines 110 function as a bit line, the second conductive lines 130 may function as a word line. The first conductive lines 110 and the second conductive lines 130 may include a single-layered structure or a multi-layered structure including one or more of various conductive materials. Examples of the conductive materials may include a metal, a metal nitride, or a conductive carbon material, or a combination thereof, but are not limited thereto. For example, the first conductive lines 110 and the second conductive lines 130 may include at least one of tungsten (W), titanium (Ti), tantalum (Ta), platinum (Pt), aluminum (Al), copper (Cu), zinc (Zn), nickel (Ni), cobalt (Co), lead (Pb), tungsten nitride (WN), tungsten silicide (WSi), titanium nitride (TiN), titanium silicon nitride (TiSiN), titanium aluminum nitride (TiAlN), tantalum nitride (TaN), tantalum silicon nitride (TaSiN), tantalum aluminum nitride (TaAlN), carbon (C), silicon carbide (SiC), or silicon carbon nitride (SiCN), or a combination thereof.

The memory cell 120 may be arranged in a matrix having rows and columns along the first direction and the second direction so as to overlap the intersection regions between the first conductive lines 110 and the second conductive lines 130. In an implementation, each of the memory cells 120 may have a size that is substantially equal to or smaller than that of the intersection region between each corresponding pair of the first conductive lines 110 and the second conductive lines 130. In another implementation, each of the memory cells 120 may have a size that is larger than that of the intersection region between each corresponding pair of the first conductive lines 110 and the second conductive lines 130.

In some implementations, the memory cell 120 may have a cylindrical shape, but the shape of the memory cell 120 is not limited thereto. In some implementations, the memory cell 120 may have a square pillar shape.

Spaces between the first conductive lines 110, the second conductive lines 130 and the memory cell 120 may be filled with an insulating material.

The memory cell 120 may include a stacked structure including a lower electrode 121, a selector pattern 122, a middle electrode 123, a memory pattern 124 and an upper electrode 125.

The lower electrode 121 shown in FIG. 2B may correspond to the electrode 10 shown in FIG. 1C. The detailed descriptions similar to those described with reference to FIGS. 1A to 1C will be omitted.

The lower electrode 121 may be interposed between the first conductive line 110 and the selector pattern 122 and disposed at a lowermost portion of each of the memory cells 120. The lower electrode 121 may function as a circuit node that carries a current or applies a voltage between one of the first conductive lines 110 and the remaining portion (e.g., the elements 122, 123, 124, and 125) of each of the memory cells 120. The middle electrode 123 may be interposed between the selector pattern 122 and the memory pattern 124. The middle electrode 123 may electrically connect the selector pattern 122 and the memory pattern 124 to each other while physically isolating or separating the selector pattern 122 and the memory pattern 124 from each other. The upper electrode 125 may be disposed at an uppermost portion of the memory cell 120 and function as a transmission path of electrical signals such as a voltage or a current between a material layer in the memory cell 120 and one of the second conductive lines 130.

Each of the middle electrode 123 and the upper electrode 125 may include a single-layered structure or a multi-layered structure including various conductive materials such as a metal, a metal nitride, a conductive carbon material, or a combination thereof. For example, the middle electrode 123 and the upper electrode 125 may include at least one of tungsten (W), titanium (Ti), tantalum (Ta), platinum (Pt), aluminum (Al), copper (Cu), zinc (Zn), nickel (Ni), cobalt (Co), lead (Pb), tungsten nitride (WN), tungsten silicide (WSi), titanium nitride (TiN), titanium silicon nitride (TiSiN), titanium aluminum nitride (TiAlN), tantalum nitride (TaN), tantalum silicon nitride (TaSiN), tantalum aluminum nitride (TaAlN), or a combination thereof.

The middle electrode 123 and the upper electrode 125 may include the same material as each other or different materials from each other.

The middle electrode 123 and the upper electrode 125 may have the same thickness as each other or different thicknesses from each other.

At least one of the middle electrode 123 and the upper electrode layer may be omitted. For example, when the upper electrode 125 is omitted, the second conductive lines 130 may perform a function of the upper electrode 125.

The lower electrode 121 may include a carbon layer. A surface of the lower electrode 121 may be planarized and hardened to have the low surface hardness. In some implementations, since a surface portion of the lower electrode 121 can have a densified structure compared to an inner portion of the lower electrode 121, etch resistance of the lower electrode 121 can be significantly increased. Compared to a conventional carbon layer formed by a sputtering method, the lower electrode 121 can have etch resistance about 3 times or more.

A lower limit of a thickness of the lower electrode 121 may be set in consideration of stabilization of the surface roughness. In some implementations, the lower limit of the thickness of the lower electrode 121 may be about 2 nm.

In some implementations, an impurity may be doped at the surface portion of the lower electrode 121. The impurity may include nitrogen, or boron, or a combination thereof. Thus, the impurity may include at least one of nitrogen or boron. When the lower electrode 121 is doped with the impurity, density and thus, resistance can be increased and a medium of the lower electrode 121 can be strengthened compared to the case where the impurity is not doped. As a result, the surface hardness of the lower electrode 121 can be further improved.

Since the lower electrode 121 includes the carbon layer and has increased surface hardness by being planarized and hardened, carbon loss caused by the ion implantation process when forming the selector pattern 122 can be prevented or minimized. Accordingly, it is possible to form the stable and uniform selector pattern 122. Since flatness of the selector pattern 122 is a very important factor that affects the stability of crystallization of the memory pattern 124, implementations of the disclosed technology suggest controlling the flatness of the selector pattern 122. In some implementations, the flatness of the selector pattern 122 can be controlled by controlling the flatness of the lower electrode 121 that is disposed under the selector pattern 122. In the implementation, since the lower electrode 121 has stable surface roughness, high surface hardness and a densified surface structure, problems such as deterioration of the film quality of the selector pattern 122 or a non-uniform operating voltage can be prevented. Further, since carbon has high resistance and high work function characteristics, a current level for operating the selector pattern 122 can be sufficiently reduced.

The selector pattern 122 may serve to control access to the memory pattern 124 and prevent a current leakage between the memory cells 120 sharing the first line 110 or the second line 130. In some implementations, the selector pattern 122 may have a threshold switching characteristic that blocks or substantially limits a current when a magnitude of an applied voltage is less than a predetermined threshold value and allows the current to increase rapidly when the magnitude of the applied voltage is equal to or greater than the predetermined threshold value. This threshold value may be referred to as a threshold voltage, and the selector pattern 122 may controlled to be in either a turned-on or “on” state to be electrically conductive or a turned-off or “off” state to be electrically less-conductive than the “on” state or electrically non-conductive depending on whether the applied voltage is above or below the threshold voltage. Thus, the selector pattern 122 exhibits different electrically conductive states to provide a switching operation to switch between the different electrical conductive states by controlling the applied voltage relative to the threshold voltage. The selector pattern 122 may include Metal Insulator Transition (MIT) material such as NbO₂, TiO₂, VO₂, WO₂, or others, Mixed Ion-Electron Conducting (MIEC) material such as ZrO₂(Y₂O₃), Bi₂O₃—BaO, (La₂O₃)ₓ(CeO₂)₁₋ₓ, or others, Ovonic Threshold Switching (OTS) material including chalcogenide material such as Ge₂Sb₂Te₅, As₂Te₃, As₂, As₂Se₃, or others, or a tunneling insulating material such as silicon oxide, silicon nitride, a metal oxide, or others. A thickness of the tunneling insulating layer is sufficiently small to allow tunneling of electrons through the tunneling insulating layer under a given voltage or a given current. The selector pattern 122 may include a single-layered structure or a multi-layered structure.

The selector pattern 122 may include a first selector pattern 122-1 and a second selector pattern 122-2.

The first selector pattern 122-1 may be disposed over the lower electrode 121 and include a nitride with a dopant.

The nitride included in the first selector pattern 122-1 may include silicon nitride, titanium nitride, aluminum nitride, tungsten nitride, hafnium nitride, tantalum nitride, niobium nitride, yttrium nitride, or zirconium nitride, or a combination thereof.

The dopant included in the first selector pattern 122-1 may include an n-type dopant or a p-type dopant. The dopant may include one or more of boron (B), nitrogen (N), carbon (C), phosphorous (P), arsenic (As), aluminum (Al), silicon (Si), gallium (Ga), tungsten (W), antimony (Sb) or a germanium (Ge).

The second selector pattern 122-2 may be disposed over the first selector pattern 122-2 and include an oxide with a dopant.

The oxide included in the second selector pattern 122-2 may include silicon oxide, titanium oxide, aluminum oxide, tungsten oxide, hafnium oxide, tantalum oxide, niobium oxide, yttrium oxide, or zirconium oxide, or a combination thereof.

The dopant included in the second selector pattern 122-2 may include an n-type dopant or a p-type dopant. The dopant may include one or more of boron (B), nitrogen (N), carbon (C), phosphorous (P), arsenic (As), aluminum (Al), silicon (Si), gallium (Ga), tungsten (W), antimony (Sb) or a germanium (Ge).

Since the selector pattern 122 is formed over the lower electrode 121 having a planarized and hardened surface, the selector pattern 122 can have a good flatness characteristic and thus contribute to stable crystallization when forming the memory pattern 124.

The memory pattern 124 may be used to store data by switching between different resistance states according to an applied voltage or current. The memory pattern 124 may have a single-layered structure or a multi-layered structure including at least one of materials having a variable resistance characteristic used for an RRAM, a PRAM, an MRAM, an FRAM, and others. For example, the memory pattern 124 may include a metal oxide such as a transition metal oxide or a perovskite-based oxide, a phase change material such as a chalcogenide-based material, a ferromagnetic material, a ferroelectric material, or others. However, the implementations are not limited thereto, and the memory cell 120 may include other variable resistance layers capable of storing data in various ways instead of the memory pattern 124.

In some implementations, the memory pattern 124 may include an MTJ structure including a free layer having a variable magnetization direction, a pinned layer having a pinned magnetization direction and a tunnel barrier layer interposed between the free layer and the pinned layer.

The free layer may have one of different magnetization directions or one of different spin directions of electrons to switch the polarity of the free layer in the MTJ structure, resulting in changes in resistance value. In some implementations, the polarity of the free layer is changed or flipped upon application of a voltage or current signal (e.g., a driving current above a certain threshold) to the MTJ structure. With the polarity changes of the free layer, the free layer and the pinned layer have different magnetization directions or different spin directions of electron, which allows the memory pattern 124 to store different data or represent different data bits. The free layer may also be referred as a storage layer. The magnetization direction of the free layer may be substantially perpendicular to a surface of the free layer, the tunnel barrier layer and the pinned layer. In other words, the magnetization direction of the free layer may be substantially parallel to stacking directions of the free layer, the tunnel barrier layer and the pinned layer. Therefore, the magnetization direction of the free layer may switch between a downward direction and an upward direction. The change in the magnetization direction of the free layer may be induced by a spin transfer torque generated by an applied current or voltage.

The pinned layer may have a pinned magnetization direction, which remains unchanged while the magnetization direction of the free layer changes. The pinned layer may be referred to as a reference layer. In some implementations, the magnetization direction of the pinned layer may be pinned in a downward direction. In some implementations, the magnetization direction of the pinned layer may be pinned in an upward direction.

The free layer and the pinned layer may have a single-layered structure or a multi-layered structure including a ferromagnetic material. For example, the pinned layer may include an alloy based on Fe, Ni or Co, for example, an Fe—Pt alloy, an Fe—Pd alloy, a Co—Pd alloy, a Co—Pt alloy, a Co—Fe alloy, an Fe—Ni—Pt alloy, a Co—Fe—Pt alloy, a Co—Ni—Pt alloy, or a Co—Fe—B alloy, or may include a stack of metals, such as Co/Pt, or Co/Pd or others.

The tunnel barrier layer may allow the tunneling of electrons in both data reading and data writing operations. The tunnel barrier layer may include a dielectric oxide such as MgO, CaO, SrO, TiO, VO, or NbO or others.

If a voltage or current is applied to the memory pattern 124, the magnetization direction of the free layer may switch between a downward direction and an upward direction by spin transfer torque. In some implementations, when the magnetization directions of the free layer and the pinned layer are parallel to each other, the memory pattern 124 may be in a low resistance state, and this may indicate digital data bit “0.” Conversely, when the magnetization directions of the free layer and the pinned layer are anti-parallel to each other, the memory pattern 124 may be in a high resistance state, and this may indicate a digital data bit “1.” In some implementations, the memory pattern 124 can be configured to store data bit ‘1’ when the magnetization directions of the free layer and the pinned layer are parallel to each other and to store data bit ‘0’ when the magnetization directions of the free layer and the pinned layer are anti-parallel to each other.

In some implementations, the memory pattern 124 may further include one or more layers performing various functions to improve a characteristic of the MTJ structure. For example, the memory pattern 124 may further include at least one of a buffer layer, an under layer, a spacer layer, a magnetic correction layer, and a capping layer.

The memory pattern 124 may have a single-layered structure or a multi-layered structure including at least one of materials having a variable resistance characteristic. However, the implementations are not limited thereto, and the memory cell 120 may include other variable resistance layers capable of storing data in various ways instead of the memory pattern 124.

In some implementations, each of the memory cells 120 includes the lower electrode 121, the selector pattern 122, the middle electrode 123, the memory pattern 124 and the upper electrode 125 which are sequentially stacked. The structures of the memory cells 120 may be varied without being limited to one as shown in FIGS. 1A and 1B as long as the memory cells 120 have data storage properties. In some implementations, at least one of the middle electrode 123 and the upper electrode layer 125 may be omitted. In some implementations, relative positions of the memory pattern 124 and the selector pattern 122 may be reversed. In some implementations, in addition to the layers 121, 122, 123, 124 and 125 shown in FIG. 2B, the memory cells 120 may further include one or more layers (not shown) for enhancing characteristics of the memory cells 120 or improving fabricating processes. For example, the memory cell 120 may include at least one of a lower electrode contact and an upper electrode contact. Further, a hard mask pattern may remain.

In some implementations, neighboring memory cells of the plurality of memory cells 120 may be spaced apart from each other at a predetermined interval, and trenches may be present between the plurality of memory cells 120. A trench between neighboring memory cells 120 may have a height to width ratio (i.e., an aspect ratio) in a range from 1:1 to 40:1, from 10:1 to 40:1, from 10:1 to 20:1, from 5:1 to 10:1, from 10:1 to 15:1, from 1:1 to 25:1, from 1:1 to 30:1, from 1:1 to 35:1, or from 1:1 to 45:1.

In some implementations, the trench may have sidewalls that are substantially perpendicular to an upper surface of the substrate 100. In some implementations, neighboring trenches may be spaced apart from each other by an equal or similar distance.

Although one cross-point structure has been described, two or more cross-point structures may be stacked in a vertical direction perpendicular to a top surface of the substrate 100.

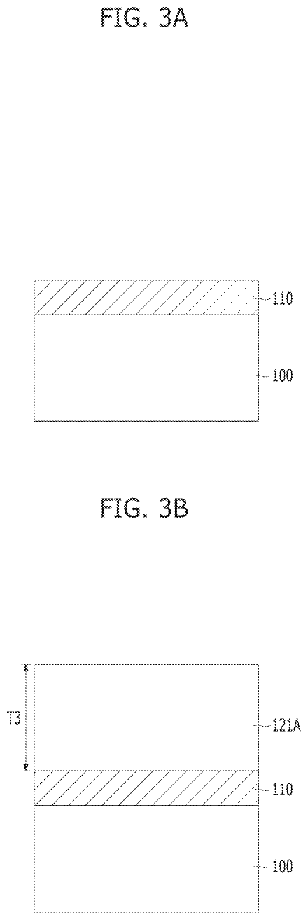

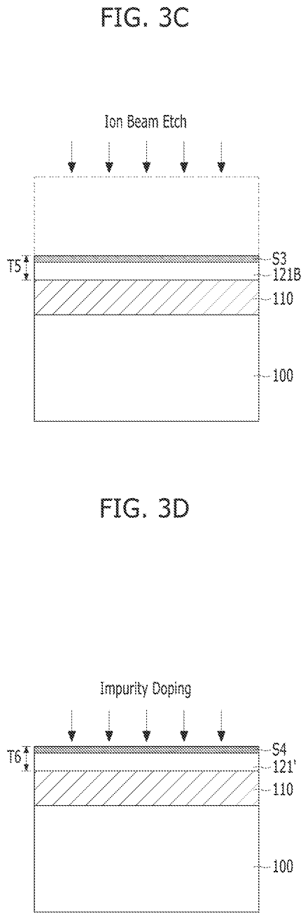

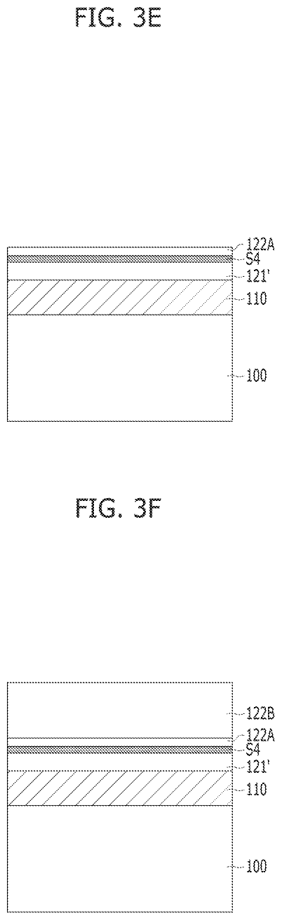

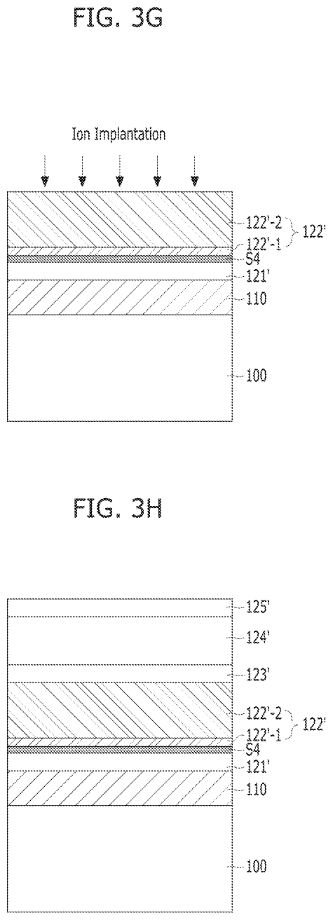

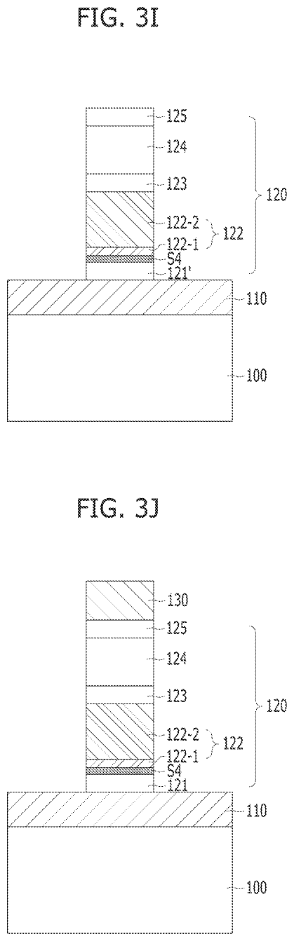

A method for fabricating a semiconductor device will be explained with reference to FIGS. 3A to 3J. The detailed descriptions similar to those described in FIGS. 1A to 1C, 2A and 2B will be omitted. In the below descriptions, a lower electrode layer 121′, a selector layer 122′, a middle electrode layer 123′, a memory layer 124′ and an upper electrode layer 125′ may represent material layers to form a lower electrode 121, a selector pattern 122, a middle electrode 123, memory pattern 124 and an upper electrode 125, respectively, by a patterning process.

Referring to FIG. 3A, first conductive lines 110 may be formed over a substrate 100 in which a predetermined structure is formed. For example, the first conductive lines 110 may be formed by forming a conductive layer for the first conductive lines 110 over the substrate 200 and etching the conductive layer using a mask pattern in a line shape extending in a first direction. The first conductive lines 110 may have a single-layered structure or a multi-layered structure including a conductive material.

Referring to FIG. 3B, a carbon layer 121A may be formed over the first conductive lines 110.

The carbon layer 121A may be formed to have a thickness T4.

The carbon layer 121A may be formed by a physical vapor deposition method, for example, a sputtering method.

As discussed referring to FIG. 3C, an ion beam etch process may be performed on the carbon layer 121A. The carbon layer 121A in which the thickness is decreased and a surface is planarized and hardened by the ion beam etch process may be referred to as an initial lower electrode layer 121B.

Since the carbon layer 121A is deposited by a sputtering method or others, the surface roughness is poor and the layer is unstable, in the implementation, by performing an ion beam etch process on the carbon layer 121A, remaining carbon layer 121A (that is, the initial electrode 121B) can remain with a very thin thickness enough to facilitate electrode isolation and maintain the surface roughness stably. Thus, the surface of the initial electrode 121B can be planarized to exhibit sufficiently reduced surface roughness. A surface portion of the initial electrode 121B is more densified than an inner portion of the initial electrode 121B. Therefore, the initial electrode 121B can have etch resistance about 3 times or more than that of the carbon layer 121A. In the initial electrode 121B, a surface portion that is planarized and has an increased hardness may be referred to as S3.

A lower limit of a thickness T5 of the initial lower electrode layer 121B may be set in consideration of stabilization of the surface roughness. In some implementations, the lower limit of the thickness T5 may be about 2 nm. An upper limit of the thickness T5 of the initial lower electrode layer 121B may vary depending on the thickness T4 of the carbon layer 121A. As the thickness T4 of the carbon layer 121A increases, the thickness T5 of the initial electrode 121B may also increase.

Referring to FIG. 3D, the impurity doping process may be performed such that the initial lower electrode layer 121B may be doped with an impurity. The initial lower electrode layer 121B doped with the impurity may be referred to as the lower electrode layer 121′.

Density of the lower electrode layer 121′ can be increased by impurity doping, and thus resistance can be increased. Therefore, a medium of the lower electrode layer 121′ can be strengthened. As a result, the surface hardness of the lower electrode layer 121′ can be further increased by the impurity doping process.

In the lower electrode layer 121′, a surface portion having an increased hardness may be referred to as S4.

The impurity may include nitrogen (N), or boron (B), or a combination thereof. Thus, the impurity may include at least one of nitrogen (N) or boron (B).

The impurity doping process may be performed by a low energy ion implantation process or a plasma doping (PLAD) process. By doping the impurity through the low energy ion implantation process or the PLAD process, density and thus resistance of the lower electrode layer 121′ can be increased to strengthen a medium of the lower electrode layer 121′. Further, it is possible to increase the surface hardness and prevent deterioration of the surface roughness.

In some implementations, the low energy ion implantation process may be performed under conditions including an energy of 1-5 KeV and a dose of 1.0×10¹³−1.0×10¹⁶ cm⁻².

In some implementations, the PLAD process may be performed under conditions including an energy of 1-5 KV and a dose of 1.0×10¹³−1.0×10¹⁶ cm⁻².

The lower electrode layer 121′ can have further improved surface hardness by providing an additional surface strengthening and medium reinforcing effect for the initial lower electrode layer 121B having a planarized surface and improved surface hardness.

The lower electrode layer 121′ may be formed to have a thickness T6. Since an upper portion of the initial lower electrode layer 121B is partially lost during the ion implantation process, the thickness T6 of the lower electrode layer 121′ may be smaller than the thickness T5 of the initial lower electrode layer 121B.

The impurity doping process may be optionally performed. That is, in some implementations, a nitride layer 122A may be formed over the initial lower electrode layer 121B as shown in FIG. 3E without the impurity doping process after the ion beam etch process. The impurity doping process may be an optional process for strengthen the medium and improving the surface hardness.

Referring to FIG. 3E, the nitride layer 122A may be formed over the lower electrode layer 121′.

The nitride layer 122A may serve to prevent loss of carbon in the lower electrode layer 121′ due to a subsequent ion implantation process and protect the lower electrode layer 121′. The nitride layer 122A may be converted into a first selector layer 122′-1 by the ion implantation process and then formed as a first selector pattern 122-1.

The nitride layer 122A may include at least one of silicon nitride, titanium nitride, aluminum nitride, tungsten nitride, hafnium nitride, tantalum nitride, niobium nitride, yttrium nitride, or zirconium nitride, or a combination thereof.

Since the nitride layer 122A is converted into a part of the selector pattern 122, a thickness of the nitride layer 122A may be set to secure a stable thickness of the selector pattern 122. In some implementations, the selector pattern 122 may be formed to have a thickness of about 5-7 nm. If the thickness of the selector pattern 122 is too thick, resistance increases, and Vf (Forward voltage) and Vth (Threshold voltage) become high so that a forming fail may be caused. If the thickness of the selector pattern 122 is too thin, resistance becomes very small so that a breakdown fail may be caused. Accordingly, in order for the selector pattern 122 to have a stable thickness, the thickness of the nitride layer 122A and a thickness of an oxide layer 122B needs to be appropriately controlled. In some implementations, considering this aspect, the nitride layer 122A may have a thickness of 1-2 nm.

Referring to FIG. 3F, the oxide layer 122B may be formed over the nitride layer 122A.

The oxide layer 122B may be converted into a second selector layer 122′-2 by a subsequent ion implantation process and then formed as a second selector layer 122′-2.

The oxide layer 122B may include at least one of silicon oxide, titanium oxide, aluminum oxide, tungsten oxide, hafnium oxide, tantalum oxide, niobium oxide, yttrium oxide, or zirconium oxide, or a combination thereof.

Since the oxide layer 122B is converted into a part of the selector pattern 122, a thickness of the oxide layer 122B may be set to secure a stable thickness of the selector pattern 122. As described above, in order for the selector pattern 122 to have a stable thickness, the thickness of the nitride layer 122A and a thickness of the oxide layer 122B needs to be appropriately controlled. In some implementations, considering this aspect, the oxide layer 122B may have a thickness of 6-12 nm.

Referring to FIG. 3G, an ion implantation process may be performed on the nitride layer 122A and the oxide layer 122B.

A dopant doped by the ion implantation process may include an n-type dopant or a p-type dopant. The dopant may include one or more of boron (B), nitrogen (N), carbon (C), phosphorous (P), arsenic (As), aluminum (Al), silicon (Si), gallium (Ga), tungsten (W), antimony (Sb) or a germanium (Ge).

The nitride layer 122A and the oxide layer 122B may be converted into the first selector layer 122′-1 and the second selector layer 122′-2, respectively, to form the selector layer 122′.

Referring to FIG. 3H, the middle electrode layer 123′, the memory layer 124′ and the upper electrode layer 125′ may be sequentially formed over the selector layer 122′.

The middle electrode layer 123′ and the upper electrode layer 125′ may include various conductive materials, for example, a metal, a nitride, or a silicide-based material, or a combination thereof.

The memory layer 124′ may have a single-layered structure or a multi-layered structure including at least one of materials having a variable resistance characteristic used for an RRAM, a PRAM, an MRAM, an FRAM, and others. For example, the memory layer 124′ may have a single-layered structure or a multi-layered structure including at least one of materials having a variable resistance characteristic used for an RRAM, a PRAM, an MRAM, an FRAM, and others.

Referring to FIG. 3I, a memory cell 120 in which the lower electrode 121, the selector pattern 122, the middle electrode 123, the memory pattern 124 and the upper electrode 125 are sequentially stacked may be formed by etching the upper electrode layer 125′, the memory layer 124′, the middle electrode layer 123′, the selector layer 122′ and the lower electrode layer 121′ by using a hard mask pattern.

Referring to FIG. 3J, second conductive lines 130 may be formed over the upper electrode 125. The second conductive lines 130 may be formed by forming a conductive layer for forming the second conductive lines 130 and etching the conductive layer by using a mask pattern in a line shape extending in a second direction.

Through the above-described process, the semiconductor memory shown in FIG. 2B may be formed. The semiconductor device may include the first conductive lines 110, the memory cell 120 and the second conductive lines 130 which are sequentially formed over the substrate. The memory cell 120 may include the lower electrode 121, the selector pattern 122, the middle electrode 123, the memory pattern 124 and the upper electrode 125 which are sequentially stacked.

The lower electrode 121 may include a carbon layer and have the low surface roughness by being planarized and hardened. In some implementations, since the surface portion of the lower electrode 121 can have a densified structure compared to the inner portion of the lower electrode 121, etch resistance of the lower electrode 121 can be significantly increased. Compared to a conventional carbon layer formed by a sputtering method, the surface of the lower electrode 121 can have etch resistance about 3 times or more. In some implementations, the surface of the lower electrode 121 may be doped with the impurity to strengthen the medium of the lower electrode 121 and increase the surface hardness.

The selector pattern may include the first selector pattern 122-1 including the nitride and the dopant and the second selector pattern 122-2 including the oxide and the dopant.

Advantages of the implementation will be described in comparison with a comparative example.

The comparative example in which a lower electrode is formed by sputtering a carbon layer is advantageous in terms of high resistance and high work function characteristics compared to the case where a lower electrode is formed of a metal, a nitride-based material or a silicide-based material. Further, even if a part of carbon lost by ion implantation when forming a selector pattern is scattered in the selector layer, deterioration of the characteristics of the selector pattern does not occur. However, since the carbon layer is deposited by a sputtering method or others, the surface roughness is poor and the layer is unstable, which causes carbon to be easily lost and makes it difficult to preserve a shape of the lower electrode. Further, the flatness of the selector pattern is important in terms of characteristic of a memory cell and the flatness of the selector pattern needs to be controlled together with the flatness of the lower electrode disposed under the selector pattern. Since the lower electrode formed of carbon deposited by the sputtering method has the poor surface roughness, it is difficult to form the stable and uniform selector pattern.

In the implementations, when forming the lower electrode 121, through performing the ion beam etch process to the carbon layer 121A, the thickness can be sufficiently reduced and the surface roughness can be maintained in more stable manner. Further, the loss of carbon due to the ion implantation process when forming the selector layer 122′ can be prevented or minimized by increasing the surface hardness. In addition, by performing the impurity doping process, it is possible to further strengthen the lower electrode 121 and increase the surface hardness of the lower electrode 121. In some implementations, as the flatness of the lower electrode 121 is stably controlled, the selector pattern 122 can be stably and uniformly formed over the lower electrode 121. Further, by applying carbon having high resistance and high work function characteristics as the lower electrode 121, a current level for operating the selector pattern 122 can be sufficiently lowered.

In the implementation, the ion beam etch process and the impurity doping process are performed for forming the lower electrode 121. In another implementation, the impurity doping process may be omitted.

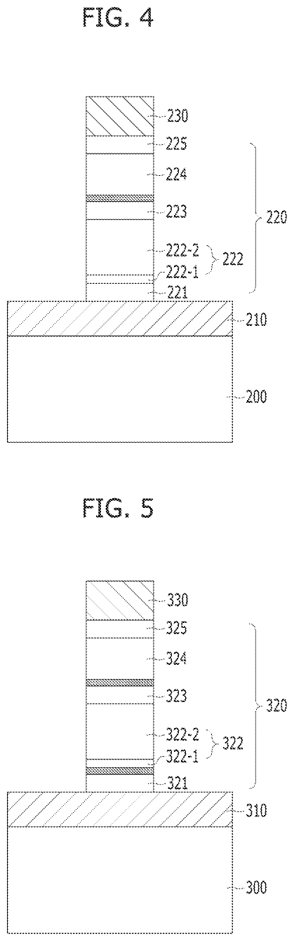

In the implementation, the lower electrode 121 is formed by the process shown in FIGS. 1A to 1C. In another implementation, the middle electrode 123, or both the lower electrode 121 and the middle electrode 123 may be formed by the process shown in FIGS. 1A to 1C. This will be described with reference to FIGS. 4 and 5.

FIGS. 4 and 5 illustrate another example of a semiconductor device based on some implementations of the disclosed technology. The descriptions will be focused on differences from the implementations shown in FIGS. 1A to 1C, FIGS. 2A and 2B and FIGS. 3A to 3J.

Referring to FIG. 4, the semiconductor device is similar to the implementations shown in FIGS. 2A and 2B and FIGS. 3A to 3J except that a middle electrode 223 instead of a lower electrode 221 is formed by the process shown in FIGS. 1A to 1C. Thus, the semiconductor device may include first conductive lines 210, a memory cell 220 and second conductive lines 230 which are sequentially formed over a substrate 200. The memory cell 220 may include a lower electrode 221, a selector pattern 222, the middle electrode 223, a memory pattern 224 and an upper electrode 225 which are sequentially stacked. The selector pattern 222 may include a first selector pattern 222-1 and a second selector pattern 222-2.

The middle electrode 223 may be formed by the process shown in FIGS. 1A to 1C. The middle electrode layer 223 may include a carbon layer and have the low surface roughness by planarizing and hardening the surface. In addition, since a surface portion of the middle electrode 223 can have a densified structure compared to an inner portion to have significantly increased etch resistance. In some implementations, the surface portion middle electrode 223 can be doped with an impurity to strengthen a medium and further increase the surface hardness.

The lower electrode 221 and the upper electrode 225 may be formed of a metal, a nitride, or a silicide, or a combination thereof.

The substrate 200, the first conductive lines 210, the second conductive lines 230, the selector pattern 222, the memory pattern 224 and the upper electrode 225 shown in FIG. 4 may correspond to the substrate 100, the first conductive lines 110, the second conductive lines 130, the selector pattern 122, the memory pattern 124 and the upper electrode 125 shown in FIG. 2B, respectively.

Referring to FIG. 5, the semiconductor device is similar to the implementation shown in FIGS. 2A and 2B and FIGS. 3A to 3J except that a lower electrode 321 and a middle electrode 323 are formed by the process shown in FIGS. 1A to 1C. That is, the semiconductor device may include first conductive lines 310, a memory cell 320 and second conductive lines 330 which are sequentially formed over a substrate. The memory cell 320 may include the lower electrode 321, a selector pattern 322, the middle electrode 323, a memory pattern 324 and an upper electrode 325 which are sequentially stacked. The selector pattern 322 may include a first selector pattern 322-1 and a second selector pattern 322-2.

The lower electrode 321 and the middle electrode 323 may be formed by the process shown in FIGS. 1A to 1C. The lower electrode 321 and the middle electrode 323 may include a carbon layer and have the low surface roughness by being planarized and hardened. Since surface portions of the lower electrode 321 and the middle electrode 323 can have a densified structure compared to inner portions of the lower electrode 321 and the middle electrode 323, etch resistance of the lower electrode 321 and the middle electrode 323 can be significantly increased. In some implementations, the surfaces of the lower electrode 321 and the middle electrode 323 may be doped with an impurity to strengthen a medium and increase the surface hardness. Further, it is possible to sufficiently lower a current level for operating the selector pattern 322 by using the high resistance and high work function characteristics of carbon.

The upper electrode 325 may include a metal, a nitride, or a silicide, or a combination thereof.

The substrate 300, the first conductive lines 310, the second conductive lines 330, the selector pattern 322, the memory pattern 324 and the upper electrode 325 shown in FIG. 5 may correspond to the substrate 100, the first conductive lines 110, the second conductive lines 130, the selector pattern 122, the memory pattern 124 and the upper electrode 125 shown in FIG. 2B, respectively.

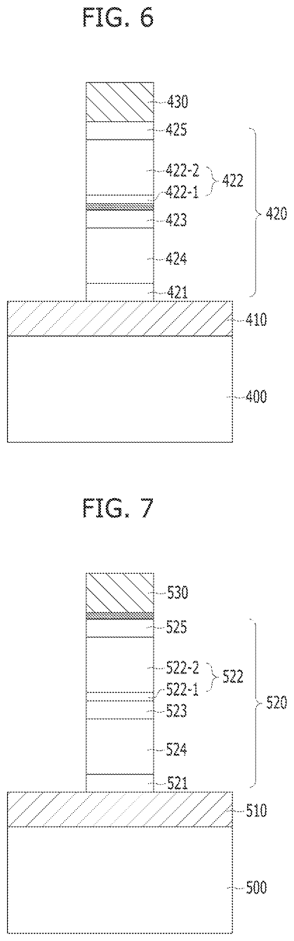

In the above-described implementations, the selector patterns 122, 222 and 322 are formed below the memory patterns 124, 224 and 324, respectively. Relative positions of the selector patterns 122, 222 and 322 and the memory patterns 124, 224 and 324 may be reversed, respectively. This will be described with reference to FIGS. 6 to 8. The descriptions will be focused on differences from the implementations shown in FIGS. 1A to 1C, FIGS. 2A and 2B, FIGS. 3A to 3J, FIGS. 4 and 5.

Referring to FIG. 6, the semiconductor device is similar to the semiconductor device shown in FIG. 2B except that a selector pattern 422 is formed over a memory pattern 424. That is, the semiconductor device may include first conductive lines 410, a memory cell 420 and second conductive lines 430 which are sequentially formed over a substrate 400. The memory cell 420 may include a lower electrode 421, the memory pattern 424, a middle electrode 423, the selector pattern 422 and an upper electrode 425 which are sequentially stacked. The selector pattern 422 may include a first selector pattern 422-1 and a second selector pattern 422-2.

The middle electrode 423 may be formed by the process shown in FIGS. 1C to 1C. The middle electrode 423 may include a carbon layer and have the low surface roughness by being strengthened and hardened. Since a surface portion of the middle electrode 423 can have a densified structure compared to an inner portion of the middle electrode 423, etch resistance of the middle electrode 423 can be significantly increased. In some implementations, the middle electrode 423 can be doped with an impurity to strengthen a medium and increase the surface hardness.

The lower electrode 421 and the upper electrode 425 may include a metal, a nitride, or a silicide, or a combination thereof.

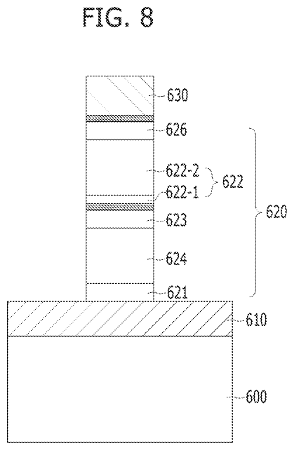

Referring to FIG. 7, the semiconductor device is similar to the semiconductor device shown in FIG. 4 except that a selector pattern 522 is formed over a memory pattern 524. That is, the semiconductor device may include first conductive lines 510, a memory cell 520 and second conductive lines 530 which are sequentially formed over a substrate 500. The memory cell 520 ma ay include a lower electrode 521, the memory pattern 524, a middle electrode 523, the selector pattern 522 and an upper electrode 525 which are sequentially stacked. The selector pattern 522 may include a first selector pattern 522-1 and a second selector pattern 522-2.

The upper electrode 525 may be formed by the process shown in FIGS. 1A to 1C. The upper electrode 525 may include a carbon layer and have the low surface roughness by being strengthened and hardened. Further, since a surface portion of the upper electrode 525 can have a densified structure compared to an inner portion of the upper electrode 525, etch resistance of the upper electrode 525 can be significantly increased. In some implementations, the surface portion of the upper electrode 525 can be doped with an impurity strengthen a medium and increase the surface hardness.

The lower electrode 521 and the middle electrode 523 may include a metal, a nitride, or a silicide, or a combination thereof.

Referring to FIG. 8, the semiconductor device is similar to the semiconductor device shown in FIG. 5 except that a selector pattern 622 is formed over a memory pattern 624. That is, the semiconductor device may include first conductive lines 610, a memory cell 620 and second conductive lines 630 which are sequentially formed over a substrate 600. The memory cell 620 may include a lower electrode 621, the memory pattern 624, a middle electrode 623, the selector pattern 622 and an upper electrode 625 which are sequentially stacked. The selector pattern 622 may include a first selector pattern 622-1 and a second selector pattern 622-2.

The middle electrode 623 and the upper electrode 625 may be formed by the process shown in FIGS. 1A to 1C. The middle electrode 623 and the upper electrode 625 may include a carbon layer and have the low surface roughness by being strengthened and hardened. Further, since surface portions of the middle electrode 623 and the upper electrode 625 can have a densified structure compared to an inner portion of the middle electrode 623 and the upper electrode 625, etch resistance of the middle electrode 623 and the upper electrode 625 can be significantly increased. In some implementations, the surface portions of the middle electrode 623 and the upper electrode 625 can be doped with an impurity to strengthen a medium and increase the surface hardness.

The lower electrode 521 may include a metal, a nitride, or a silicide, or a combination thereof.

While this patent document contains many specifics, these should not be construed as limitations on the scope of any invention or of what may be claimed, but rather as descriptions of features that may be specific to particular embodiments of particular inventions. Certain features that are described in this patent document in the context of separate embodiments can also be implemented in combination in a single embodiment. Conversely, various features that are described in the context of a single embodiment can also be implemented in multiple embodiments separately or in any suitable sub combination. Moreover, although features may be described above as acting in certain combinations and even initially claimed as such, one or more features from a claimed combination can in some cases be excised from the combination, and the claimed combination may be directed to a sub combination or variation of a sub combination.

Similarly, while operations are depicted in the drawings in a particular order, this should not be understood as requiring that such operations be performed in the particular order shown or in sequential order, or that all illustrated operations be performed, to achieve desirable results. Moreover, the separation of various system components in the embodiments described in this patent document should not be understood as requiring such separation in all embodiments.

Only a few embodiments and examples are described. Enhancements and variations of the disclosed embodiments and other embodiments can be made based on what is described and illustrated in this patent document.

What is claimed is:

1. A method for fabricating an electrode comprising:
forming a carbon layer;
performing an ion beam etch process on the carbon layer to planarize and harden a surface of the carbon layer; and
performing an impurity doping process to dope an impurity into the carbon layer.

2. The method according to claim 1, wherein the impurity doping process is performed by a low energy ion implantation process or a plasma doping process.

3. The method according to claim 2, wherein the low energy ion implantation process is performed at an energy of 1-5 KeV and a dose of 1.0×10¹³−1.0×10¹⁶ cm⁻².

4. The method according to claim 2, wherein the plasma doping process is performed at an energy of 1-5 KV and a dose of 1.0×10¹³−1.0×10¹⁶ cm⁻².

5. The method according to claim 1, wherein the impurity includes at least one of nitrogen (N) or boron (B).

6. The method according to claim 1, wherein the carbon layer after the performing of the impurity doping process has a thickness smaller than a thickness of the carbon layer prior to the performing of the impurity doping process.

7. The method according to claim 1, wherein the carbon layer after the performing of the impurity doping process has a surface hardness greater than a surface hardness of the carbon layer prior to the performing of the impurity doping process.

8. A method for fabricating a semiconductor device comprising:
forming a first electrode layer over a substrate;
forming a nitride layer and an oxide layer over the first electrode layer;
doping the nitride layer and the oxide layer with a dopant by an ion implantation process to form a selector layer; and
forming a second electrode layer over the selector layer,
wherein at least one of the forming of the first electrode layer or the forming of the second electrode layer comprises:
forming a carbon layer on the carbon layer;
performing an ion beam etch process to planarize and harden a surface of the carbon layer; and
performing an impurity doping process to dope an impurity into the carbon layer.

9. The method according to claim 8, wherein the forming of the nitride layer and the oxide layer includes forming the nitride layer to have a thickness of 1-2 nm.

10. The method according to claim 8, wherein the forming of the nitride layer and the oxide layer includes forming the oxide layer to have a thickness of 6-12 nm.

11. The method according to claim 8, wherein the nitride layer includes at least one of silicon nitride, titanium nitride, aluminum nitride, tungsten nitride, hafnium nitride, tantalum nitride, niobium nitride, yttrium nitride, or zirconium nitride,
wherein the oxide layer includes at least one of silicon oxide, titanium oxide, aluminum oxide, tungsten oxide, hafnium oxide, tantalum oxide, niobium oxide, yttrium oxide, or zirconium oxide, and
wherein the dopant includes at least one of boron (B), nitrogen (N), carbon (C), phosphorous (P), arsenic (As), aluminum (Al), silicon (Si), gallium (Ga), tungsten (W), antimony (Sb), or a germanium (Ge).

12. The method according to claim 8, further comprising forming a memory layer between the substrate and the first electrode layer or over the second electrode layer.

13. The method according to claim 12, wherein the forming the memory layer includes forming a selector pattern having different electrical conductive states based on an applied voltage to the memory layer.

14. The method according to claim 12, wherein the forming the memory layer includes forming a memory pattern having different resistance states according to an applied voltage to the memory layer.

15. The method according to claim 12, further forming a third electrode layer between the substrate and the memory layer or over the memory layer.

16. The method according to claim 15, wherein the third electrode layer includes at least one of a metal, a nitride, or a silicide, or a combination thereof.

17. The method according to claim 8, wherein the performing of the impurity doping process includes performing a low energy ion implantation process or a plasma doping process.

18. The method according to claim 17, wherein the low energy ion implantation process is performed at an energy of 1-5 KeV and a dose of 1.0×10¹³−1.0×10¹⁶ cm⁻².

19. The method according to claim 17, wherein the plasma doping process is performed at an energy of 1-5 KV and a dose of 1.0×10¹³−1.0×10¹⁶ cm⁻².

20. The method according to claim 8, wherein the impurity includes at least one of nitrogen (N) or boron (B).
